(19) United States
(12) Patent Application Publication
(10) Pub. No.: US 2016/0380722 A1
(43) Pub. Date: Dec. 29, 2016

(54) ACCESS POINT (AP), USER STATION (STA) AND METHODS FOR VARIABLE LENGTH ENCODING AND FOR ITERATIVE DECODING

(71) Applicants: Mohamed K. Hassanin, SunnyVale, CA (US); Shahrnaz Azizi, Cupertino, CA (US); Thomas J. Kenney, Portland, OR (US); Eldad Perahia, Portland, OR (US); Ahmed Gamal Helmy Mohamed, Santa Clara, CA (US)

(72) Inventors: Mohamed K. Hassanin, SunnyVale, CA (US); Shahrnaz Azizi, Cupertino, CA (US); Thomas J. Kenney, Portland, OR (US); Eldad Perahia, Portland, OR (US); Ahmed Gamal Helmy Mohamed, Santa Clara, CA (US)

(21) Appl. No.: 14/751,064

(22) Filed: Jun. 25, 2015

(51) Int. Cl. H04L 1/00; H03M 13/00; H03M 13/11

(52) U.S. Cl. CPC H04L 1/0041; H03M 13/1102; H03M 13/616; H04L 1/0045

(57) ABSTRACT

Embodiments of an access point (AP), user station (STA), and method for variable length encoding are generally described herein. The AP may encode a block of input bits according to a parity check matrix to produce a low density parity check (LDPC) codeword. The parity check matrix may be included in a group of candidate parity check matrixes that includes a base parity check matrix and an expanded parity check matrix. An LDPC codeword length may be smaller for the base parity check matrix than for the expanded parity check matrix. The base parity check matrix may be used for the encoding when the LDPC codeword is transmitted for a legacy user station (STA). The expanded parity check matrix may be used when the LDPC codeword is transmitted for a non-legacy STA.

### TECHNICAL FIELD

Embodiments pertain to wireless networks. Some embodiments relate to wireless local area networks (WLANs) and Wi-Fi networks including networks operating in accordance with the IEEE 802.11 family of standards, such as the IEEE 802.11ac standard or the IEEE 802.11ax study group (SG) (named DensiFi). Some embodiments relate to high-efficiency (HE) wireless or high-efficiency WLAN or Wi-Fi (HEW) communications. Some embodiments relate to multi-user (MU) multiple-input multiple-output (MIMO) communications and orthogonal frequency division multiple access (OFDMA) communication techniques. Some embodiments relate to decoding techniques, including iterative decoding.

### BACKGROUND

Wireless communications has been evolving toward ever increasing data rates (e.g., from IEEE 802.11a/g to IEEE 802.11n to IEEE 802.11ac). In high-density deployment situations, overall system efficiency may become more important than higher data rates. For example, in high-density hotspot and cellular offloading scenarios, many devices competing for the wireless medium may have low to moderate data rate requirements (with respect to the very high data rates of IEEE 802.11ac). A recently-formed study group for Wi-Fi evolution referred to as the IEEE 802.11 High Efficiency WLAN (HEW) study group (SG) (i.e., IEEE 802.11 ax) is addressing these high-density deployment scenarios.

### BRIEF DESCRIPTION OF THE DRAWINGS

FIG. 1 illustrates a wireless network in accordance with some embodiments;

FIG. 2 illustrates a user station (STA) and an access point (AP) in accordance with some embodiments;

FIG. 3 illustrates the operation of a method of communication using low density parity check (LDPC) codes in accordance with some embodiments;

FIG. 4 illustrates a sub-matrix representation of an example parity check matrix in accordance with some embodiments;

FIG. 5 illustrates an example arrangement of orthogonal frequency division multiplexing (OFDM) symbol periods and sub-carriers in accordance with some embodiments;

FIG. 6 illustrates the operation of another method of communication using LDPC codes in accordance with some embodiments;

FIG. 7 illustrates an example of an iterative decoder in accordance with some embodiments; and

FIG. 8 illustrates an example of a parity check matrix that may be used for iterative decoding in accordance with some embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

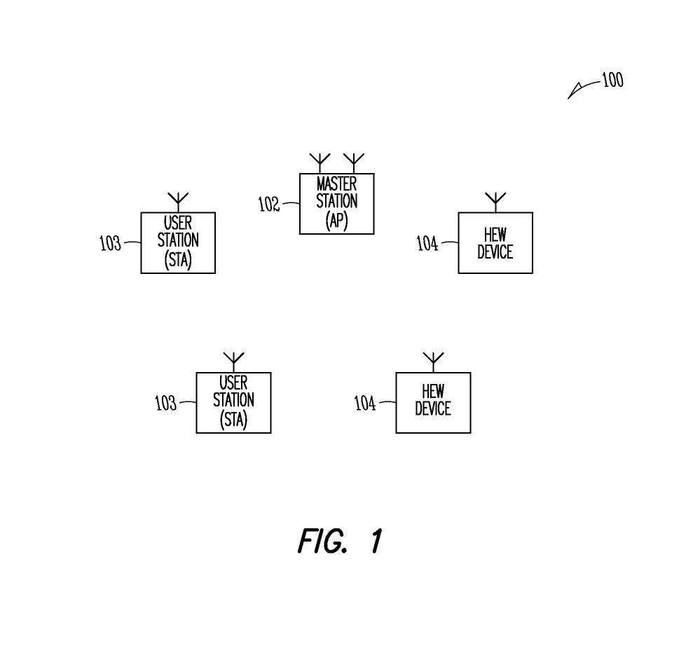

FIG. 1 illustrates a wireless network in accordance with some embodiments. In some embodiments, the network 100 may be a High Efficiency Wireless Local Area Network (HEW) network. In some embodiments, the network 100 may be a Wireless Local Area Network (WLAN) or a Wi-Fi network. These embodiments are not limiting, however, as some embodiments of the network 100 may include a combination of such networks. That is, the network 100 may support HEW devices in some cases, non HEW devices in some cases, and a combination of HEW devices and non HEW devices in some cases. Accordingly, it is understood that although techniques described herein may refer to either a non HEW device or to an HEW device, such techniques may be applicable to both non HEW devices and HEW devices in some cases.

The network 100 may include a master station (STA) 102, a plurality of user stations (STAs) 103 and a plurality of HEW stations 104 (HEW devices). In some embodiments, the STAs 103 may be legacy stations. These embodiments are not limiting, however, as the STAs 103 may be HEW devices or may support HEW operation in some embodiments. The master station 102 may be arranged to communicate with the STAs 103 and/or the HEW stations 104 in accordance with one or more of the IEEE 802.11 standards. In accordance with some HEW embodiments, an access point may operate as the master station 102 and may be arranged to contend for a wireless medium (e.g., during a contention period) to receive exclusive control of the medium for an HEW control period (i.e., a transmission opportunity (TXOP)). The master station 102 may, for example, transmit a master-sync or control transmission at the beginning of the HEW control period to indicate, among other things, which HEW stations 104 are scheduled for communication during the HEW control period. During the HEW control period, the scheduled HEW stations 104 may communicate with the master station 102 in accordance with a non-contention based multiple access technique. This is unlike conventional Wi-Fi communications in which devices communicate in accordance with a contention-based communication technique, rather than a non-contention based multiple access technique. During the HEW control period, the master station 102 may communicate with HEW stations 104 using one or more HEW frames. During the HEW control period, STAs 103 not operating as HEW devices may refrain from communicating in some cases. In some embodiments, the master-sync transmission may be referred to as a control and schedule transmission.

In some embodiments, the AP 102 may transmit a low density parity check (LDPC) codeword for reception at the STA 103. In some embodiments, the LDPC codeword may be transmitted as part of an orthogonal frequency division multiplexing (OFDM) signal. These embodiments will be described in more detail below.

In some embodiments, the multiple-access technique used during the HEW control period may be a scheduled orthogonal frequency division multiple access (OFDMA) technique, although this is not a requirement. In some embodiments, the multiple access technique may be a time-division multiple access (TDMA) technique or a frequency division multiple access (FDMA) technique. In some embodiments, the multiple access technique may be a space-division multiple access (SDMA) technique including a multi-user (MU) multiple-input multiple-output (MIMO) (MU-MIMO) technique. These multiple-access techniques used during the HEW control period may be configured for uplink or downlink data communications.

The master station 102 may also communicate with STAs 103 and/or other legacy stations in accordance with legacy IEEE 802.11 communication techniques. In some embodiments, the master station 102 may also be configurable to communicate with the HEW stations 104 outside the HEW control period in accordance with legacy IEEE 802.11 communication techniques, although this is not a requirement.

In some embodiments, the HEW communications during the control period may be configurable to use one of 20 MHz, 40 MHz, or 80 MHz contiguous bandwidths or an 80+80 MHz (160 MHz) non-contiguous bandwidth. In some embodiments, a 320 MHz channel width may be used. In some embodiments, subchannel bandwidths less than 20 MHz may also be used. In these embodiments, each channel or subchannel of an HEW communication may be configured for transmitting a number of spatial streams.

In accordance with embodiments, a master station 102 and/or HEW stations 104 may generate an HEW packet in accordance with a short preamble format or a long preamble format. The HEW packet may comprise a legacy signal field (L-SIG) followed by one or more high-efficiency (HE) signal fields (HE-SIG) and an HE long-training field (HE-LTF). For the short preamble format, the fields may be configured for shorter-delay spread channels. For the long preamble format, the fields may be configured for longer-delay spread channels. These embodiments are described in more detail below. It should be noted that the terms “HEW” and “HE” may be used interchangeably and both terms may refer to high-efficiency Wireless Local Area Network operation and/or high-efficiency Wi-Fi operation.

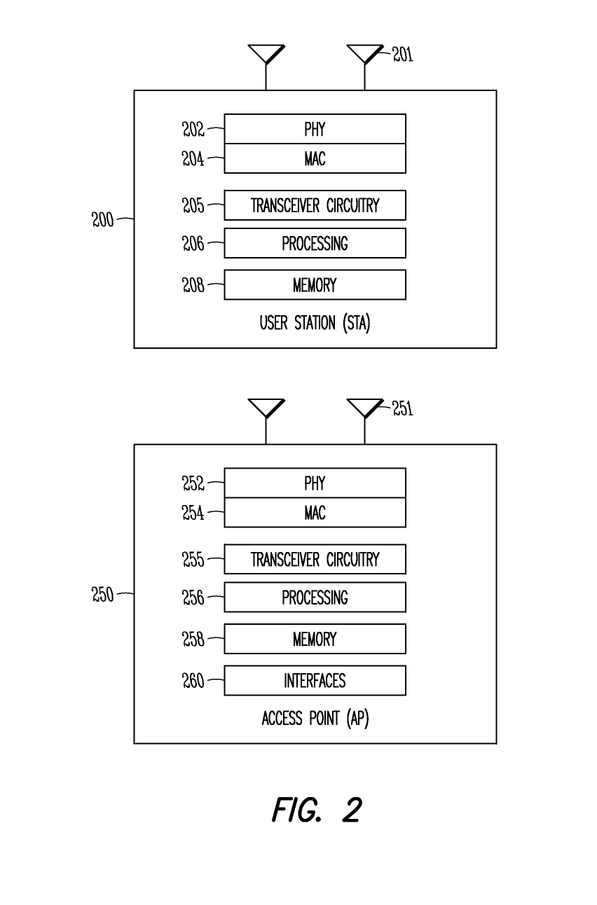

FIG. 2 illustrates a user station (STA) and an access point (AP) in accordance with some embodiments. It should be noted that in some embodiments, the AP 102 may be a stationary non-mobile device. The STA 200 may be suitable for use as an STA 103 as depicted in FIG. 1, while the AP 250 may be suitable for use as an AP 102 as depicted in FIG. 1. In addition, the STA 200 may also be suitable for use as an HEW device 104 as shown in FIG. 1, such as an HEW station.

The STA 200 may include physical layer circuitry 202 and a transceiver 205, one or both of which may enable transmission and reception of signals to and from the AP 250, other APs, other STAs or other devices using one or more antennas 201. As an example, the physical layer circuitry 202 may perform various encoding and decoding functions that may include formation of baseband signals for transmission and decoding of received signals. As another example, the transceiver 205 may perform various transmission and reception functions such as conversion of signals between a baseband range and a Radio Frequency (RF) range. Accordingly, the physical layer circuitry 202 and the transceiver 205 may be separate components or may be part of a combined component. In addition, some of the described functionality related to transmission and reception of signals may be performed by a combination that may include one, any or all of the physical layer circuitry 202, the transceiver 205, and other components or layers.

The AP 250 may include physical layer circuitry 252 and a transceiver 255, one or both of which may enable transmission and reception for transmission and reception of signals to and from the STA 200, other APs, other STAs or other devices using one or more antennas 251. The physical layer circuitry 252 and the transceiver 255 may perform various functions similar to those described regarding the STA 200 previously. Accordingly, the physical layer circuitry 252 and the transceiver 255 may be separate components or may be part of a combined component. In addition, some of the described functionality related to transmission and reception of signals may be performed by a combination that may include one, any or all of the physical layer circuitry 252, the transceiver 255, and other components or layers.

The STA 200 may also include medium access control layer (MAC) circuitry 204 for controlling access to the wireless medium, while the AP 250 may also include medium access control layer (MAC) circuitry 254 for controlling access to the wireless medium. The STA 200 may also include processing circuitry 206 and memory 208 arranged to perform the operations described herein. The AP 250 may also include processing circuitry 256 and memory 258 arranged to perform the operations described herein. The AP 250 may also include one or more interfaces 260, which may enable communication with other components, including other APs 102 (FIG. 1). In addition, the interfaces 260 may enable communication with other components that may not be shown in FIG. 1, including components external to the network 100. The interfaces 260 may be wired or wireless or a combination thereof.

The antennas 201, 251 may comprise one or more directional or omnidirectional antennas, including, for example, dipole antennas, monopole antennas, patch antennas, loop antennas, microstrip antennas or other types of antennas suitable for transmission of RF signals. In some multiple-input multiple-output (MIMO) embodiments, the antennas 201, 251 may be effectively separated to take advantage of spatial diversity and the different channel characteristics that may result.

In some embodiments, the STA 200 or the AP 250 may be a mobile device and may be a portable wireless communication device, such as a personal digital assistant (PDA), a laptop or portable computer with wireless communication capability, a web tablet, a wireless telephone, a smartphone, a wireless headset, a pager, an instant messaging device, a digital camera, an access point, a television, a wearable device such as a medical device (e.g., a heart rate monitor, a blood pressure monitor, etc.), or other device that may receive and/or transmit information wirelessly. In some embodiments, the STA 200 or AP 250 may be configured to operate in accordance with 802.11 standards, although the scope of the embodiments is not limited in this respect. Mobile devices or other devices in some embodiments may be configured to operate according to other protocols or standards, including other IEEE standards, Third Generation Partnership Project (3GPP) standards or other standards. In some embodiments, the STA 200, AP 250 or other device may include one or more of a keyboard, a display, a non-volatile memory port, multiple antennas, a graphics processor, an application processor, speakers, and other mobile device elements. The display may be an LCD screen including a touch screen.

Although the STA 200 and the AP 250 are each illustrated as having several separate functional elements, one or more of the functional elements may be combined and may be implemented by combinations of software-configured elements, such as processing elements including digital signal processors (DSPs), and/or other hardware elements. For example, some elements may comprise one or more microprocessors, DSPs, field-programmable gate arrays (FPGAs), application specific integrated circuits (ASICs), radio-frequency integrated circuits (RFICs) and combinations of various hardware and logic circuitry for performing at least the functions described herein. In some embodiments, the functional elements may refer to one or more processes operating on one or more processing elements.

Embodiments may be implemented in one or a combination of hardware, firmware and software. Embodiments may also be implemented as instructions stored on a computer-readable storage device, which may be read and executed by at least one processor to perform the operations described herein. A computer-readable storage device may include any non-transitory mechanism for storing information in a form readable by a machine (e.g., a computer). For example, a computer-readable storage device may include read-only memory (ROM), random-access memory (RAM), magnetic disk storage media, optical storage media, flash-memory devices, and other storage devices and media. Some embodiments may include one or more processors and may be configured with instructions stored on a computer-readable storage device.

It should be noted that in some embodiments, an apparatus used by the STA 200 and/or AP 250 may include various components of the STA 200 and/or AP 250 as shown in FIG. 2. Accordingly, techniques and operations described herein that refer to the STA 200 (or 103 or 104) may be applicable to an apparatus for an STA. In addition, techniques and operations described herein that refer to the AP 250 (or 102) may be applicable to an apparatus for an AP.

In some embodiments, the STA 200 may be configured as an HEW device 104 (FIG. 1), and may communicate using OFDM communication signals over a multicarrier communication channel. Accordingly, in some cases the STA 200 may be configured to receive signals in accordance with specific communication standards, such as the Institute of Electrical and Electronics Engineers (IEEE) standards including IEEE 802.11-2012, 802.11n-2009 and/or 802.11ac-2013 standards and/or proposed specifications for WLANs including proposed HEW standards, although the scope of the embodiments is not limited in this respect as they may also be suitable to transmit and/or receive communications in accordance with other techniques and standards. In some other embodiments, the STA 200 configured as an HEW device 104 may be configured to receive signals that were transmitted using one or more other modulation techniques such as spread spectrum modulation (e.g., direct sequence code division multiple access (DS-CDMA) and/or frequency hopping code division multiple access (FH-CDMA)), time-division multiplexing (TDM) modulation, and/or frequency-division multiplexing (FDM) modulation, although the scope of the embodiments is not limited in this respect.

Embodiments disclosed herein provide two preamble formats for High Efficiency (HE) Wireless LAN standards specification that is under development in the IEEE Task Group 11 ax (TGax).

In accordance with embodiments, the AP 102 may encode a block of input bits according to a parity check matrix to produce a low density parity check (LDPC) codeword. The parity check matrix may be included in a group of candidate parity check matrixes that includes a base parity check matrix and an expanded parity check matrix. An LDPC codeword length may be smaller for the base parity check matrix than for the expanded parity check matrix. In some embodiments, the base parity check matrix may be used for the encoding when the LDPC codeword is transmitted for a legacy user station STA 103. The expanded parity check matrix may be used when the LDPC codeword is transmitted for a non-legacy STA 103. These embodiments will be described in more detail below.

In some embodiments, the channel resources may be used for downlink transmission by the AP 102 and for uplink transmissions by the STAs 103. That is, a time-division duplex (TDD) format may be used. In some cases, the channel resources may include multiple channels, such as the 20 MHz channels previously described. The channels may include multiple sub-channels or may be divided into multiple sub-channels for the uplink transmissions to accommodate multiple access for multiple STAs 103. The downlink transmissions may or may not utilize the same format.

In some embodiments, the downlink sub-channels may comprise a predetermined bandwidth. As a non-limiting example, the sub-channels may each span 2.03125 MHz, the channel may span 20 MHz, and the channel may include eight or nine sub-channels. Although reference may be made to a sub-channel of 2.03125 MHz for illustrative purposes, embodiments are not limited to this example value, and any suitable frequency span for the sub-channels may be used. In some embodiments, the frequency span for the sub-channel may be based on a value included in an 802.11 standard (such as 802.11ax), a 3GPP standard or other standard.

In some embodiments, the sub-channels may comprise multiple sub-carriers. Although not limited as such, the sub-carriers may be used for transmission and/or reception of OFDM or OFDMA signals. As an example, each sub-channel may include a group of contiguous sub-carriers spaced apart by a pre-determined sub-carrier spacing. As another example, each sub-channel may include a group of non-contiguous sub-carriers. That is, the channel may be divided into a set of contiguous sub-carriers spaced apart by the pre-determined sub-carrier spacing, and each sub-channel may include a distributed or interleaved subset of those sub-carriers. The sub-carrier spacing may take a value such as 78.125 kHz, 312.5 kHz or 15 kHz, although these example values are not limiting. Other suitable values that may or may not be part of an 802.11 or 3GPP standard or other standard may also be used in some cases. As an example, for a 78.125 kHz sub-carrier spacing, a sub-channel may comprise 26 contiguous sub-carriers or a bandwidth of 2.03125 MHz.

In some embodiments, an OFDM signal may be based on different arrangements of sub-carriers during some OFDM symbol periods. As an example, a first and a second OFDM symbol period may be based on a first and second sub-carrier spacing, respectively. It should be noted that the sub-carrier spacing and the OFDM symbol period are inversely related for OFDM. Accordingly, when the second sub-carrier spacing is reduced in comparison to the first sub-carrier spacing, the second OFDM symbol period may be increased accordingly to maintain that inverse relationship. For instance, a first sub-carrier spacing of 312.5 kHz may be used along with a first OFDM symbol period of 3.2 micro-seconds (usec) (without guard intervals). A scaling of four may be applied to those numbers to produce a second sub-carrier spacing of 78.125 kHz and a second OFDM symbol period of 12.8 usec. Embodiments are not limited to integer scaling, however, as any suitable scaling factor may be used in conjunction with the inverse relationship described above. Embodiments are also not limited to the usage of two different sub-carrier spacings, as one spacing or more than two spacings may be used in some cases.

In some embodiments, a first sub-carrier spacing (and corresponding first OFDM symbol period) may be used for a system or may be included in a standard. A second sub-carrier spacing and OFDM symbol period may also be used for the system or may also be included in the standard for any suitable reason. As an example, different sub-carrier spacings and OFDM symbol periods may be desired for performance reasons. As another example, the second sub-carrier spacing and second OFDM symbol period may be related to legacy operation of the system or standard. Examples of such will be presented below.

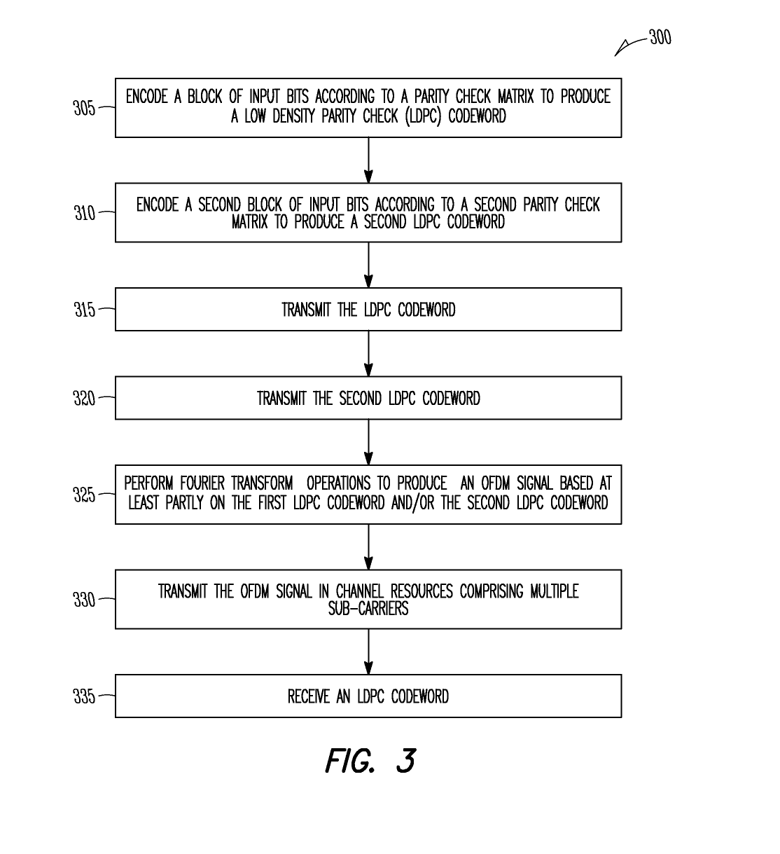

FIG. 3 illustrates the operation of a method of communication using low density parity check (LDPC) codes in accordance with some embodiments. It is important to note that embodiments of the method 300 may include additional or even fewer operations or processes in comparison to what is illustrated in FIG. 3. In addition, embodiments of the method 300 are not necessarily limited to the chronological order that is shown in FIG. 3. In describing the method 300, reference may be made to FIGS. 1-2 and 4-8, although it is understood that the method 300 may be practiced with any other suitable systems, interfaces and components.

In addition, while the method 300 and other methods described herein may refer to STAs 103 and APs 102 operating in accordance with 802.11 or other standards, embodiments of those methods are not limited to just those devices and may also be practiced on other mobile devices, such as an HEW STA, an HEW AP, an Evolved Node-B (eNB) or User Equipment (UE). In some embodiments, the STA 103 described in the method 300 may be an HEW STA 103 while the AP 102 may be an HEW AP 102. The method 300 and other methods described herein may also be practiced by wireless devices configured to operate in other suitable types of wireless communication systems, including systems configured to operate according to various Third Generation Partnership Project (3GPP) Long Term Evolution (LTE) standards. The method 300 may also refer to an apparatus for an STA 103 and/or AP 102 or other device described above.

At operation 305 of the method 300, a block of input bits may be encoded according to a parity check matrix to produce a low density parity check (LDPC) codeword. In some embodiments, the encoding may include application of a generator matrix to the block of input bits, in which the generator matrix may be based on a null space of the parity check matrix. For instance, a product of the generator matrix and the parity check matrix may be a zero vector or a zero matrix. Accordingly, a particular LDPC code may be specified in terms of the parity check matrix and/or the generator matrix. In some embodiments, the parity check matrix and the generator matrix may include binary numbers with two possible values (0 and 1), although arrangements with more possible values than two may be possible in some cases. For instance, M-ary numbers, with M larger than two, may be used in some embodiments. It should be noted that the LDPC code may be included as part of one or more 802.11 standards or other standards, but embodiments are not limited to these particular codes. As an example, other LDPC codes may be used, and may or may not be part of an 802.11 standard or other standard.

In some embodiments, the parity check matrix may include a group of sub-matrixes arranged within the parity check matrix according to a grid pattern. A size of the sub-matrixes may be varied to produce parity check matrixes of different sizes, which may result in different LDPC codeword lengths.

At operation 310 of the method 300, a second block of input bits may be encoded according to a second parity check matrix to produce a second LDPC codeword. The encoding may use similar techniques as operation 305, although not limited as such. In some embodiments, the parity check matrixes used for operations 305 and 310 may be of different sizes. Accordingly, code rates, LDPC codeword lengths, and/or input block sizes may be different for those parity check matrixes in some cases.

In some embodiments, a group of candidate parity check matrixes may include a base parity check matrix and an expanded parity check matrix. As a non-limiting example, operations 305 and 310 may use the base parity check matrix and the expanded parity check matrix. Embodiments are not limited to two candidate parity check matrixes, however, as the group may include more than two candidate parity check matrixes in some embodiments. Some embodiments may include one candidate parity check matrix.

The base parity check matrix may include a group of base sub-matrixes of a base size and the expanded parity check matrix may include a group of expansions of the base sub-matrixes. The expansions may be of an expanded size and may be expanded versions of the base sub-matrixes, with larger dimensions. That is, the expanded size may be larger than the base size. Accordingly, an LDPC codeword length may be smaller for an LDPC code that uses the base parity check matrix than for an LDPC code that uses the expanded parity check matrix.

In some embodiments, the base sub-matrixes may include one or more zero matrixes (in which all of the entries are “0”) of the base size and one or more identity matrixes (a matrix with a value of “1” on the principle diagonal and “0” elsewhere) of the base size shifted by a set of shift values. The expansions of the group of base sub-matrixes may include zero matrixes of an expanded size and may include identity matrixes of the expanded size shifted by the set of shift values. Although not limited, parity check matrixes that include zero matrixes and shifted identity matrixes may generate quasi-cyclic LDPC codes (QC-LDPCC).

In some embodiments, the base sub-matrixes may be arranged within the base parity check matrix according to a grid pattern. The expanded parity check matrixes may be arranged within the expanded parity check matrix according to the same grid pattern of the base parity check matrix. For instance, each sub-matrix may be indicated by a grid index, which may include a row and a column within the grid pattern. In some embodiments, for grid indexes at which the base parity check matrix includes zero matrixes, the expanded parity check matrix may include zero matrixes. In addition, for grid indexes at which the base parity check matrix includes shifted identity matrixes, the expanded parity check matrix may include shifted identity matrixes.

It should also be noted that the group of candidate parity check matrixes may further include additional parity check matrixes, such as a second expanded parity check matrix. Accordingly, the second expanded parity check matrix may include zero matrixes of a second expanded size and identity matrixes of the second expanded size shifted by the set of shift values used for the base parity check matrix. In some embodiments, additional expanded parity check matrixes and/or other parity check matrixes may be included in the group of candidate parity check matrixes.

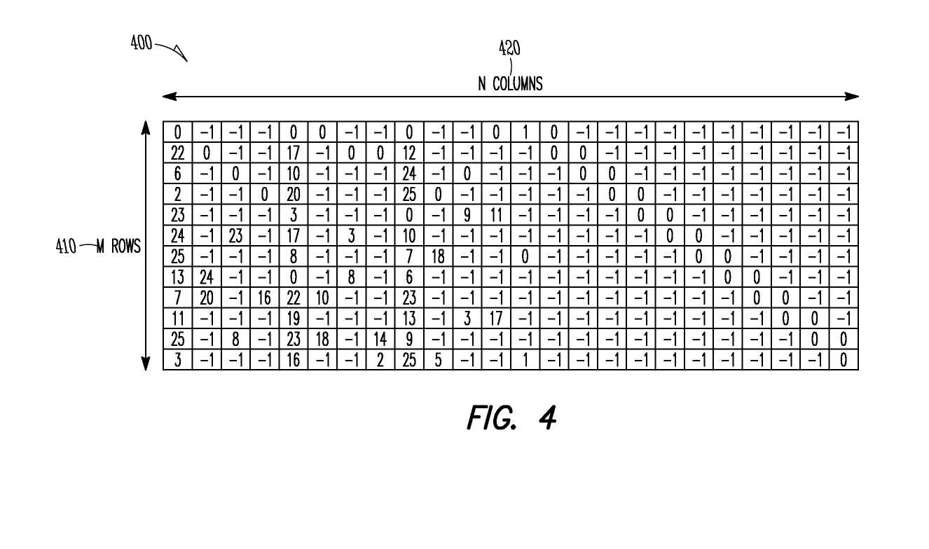

FIG. 4 illustrates a sub-matrix representation of an example parity check matrix in accordance with some embodiments. The parity check matrix may be formed from the sub-matrix representation 400, which includes a matrix of M=12 rows 410 and N=24 columns 420 in the example. Each of the entries of the sub-matrix representation 400 may represent a square sub-matrix of dimension k. Accordingly, the parity check matrix may be of dimension (Mk×Nk). It should be noted that the representation 400 may indicate the parity check matrix in an abbreviated notation, but embodiments are not limited to the use of this representation 400. It should also be noted that embodiments are not necessarily limited to square sub-matrixes, although square sub-matrixes are used in this example. Embodiments are also not limited to the usage of sub-matrixes at all, as parity check matrixes in different formats may also be used in some cases.

An entry of “−1” in the matrix representation 400 may indicate a square matrix of zeros for the sub-matrix. An entry of “0” or a positive number, like 22, 6, 2, 23, and others in the first (left-most) column 420, may be a shift value, and may indicate a shifted identity matrix for the sub-matrix. That is, an identity matrix of dimension k may be cyclically shifted by the shift value to produce the sub-matrix. It should be noted that an entry of “0” may therefore represent an identity matrix that is not shifted.

The arrangement of the entries by rows 410 and columns 420 of the matrix representation 400 may indicate a grid pattern. That is, an entry of the matrix representation 400 may be identified by a location in terms of its row 410 and column 420, and may be a grid index as previously described. Accordingly, the parity check matrix may also follow the grid pattern, in some embodiments. That is, the entries of a particular column 420 may indicate a column-wise series of sub-matrixes that may be concatenated vertically as part of the parity check matrix. The entries of a particular row 410 may indicate a row-wise series of sub-matrixes that may be concatenated horizontally as part of the parity check matrix. As a non-limiting example, a grid index related to the (i,j)th element (ith row and jth column) of the matrix representation 400 may indicate a sub-matrix for the parity check matrix located between row (i*k) and row (i*k+k−1) and between column (j*k) and column (j*k+k−1). The indexing for this example may begin at 0 for both matrixes. For instance, i may be in the range of 0, 1, . . . (M−1) and j may be in the range 0, 1, (N−1).

In some embodiments, an LDPC codeword length (and therefore a parity check matrix) may be selected according to any suitable reason. As an example, a legacy STA 103 may support a first LDPC codeword length that results from usage of the base parity check matrix. Another STA 103, such as a non-legacy STA 103, may support longer codeword lengths and may therefore use the expanded parity check matrix. In some cases, the non-legacy STA 103 may be configured to use either the base or the expanded parity check matrix. In addition, some embodiments may include more than two candidate parity check matrixes, and the non-legacy STA 103 may be configured to support any or all of the candidate parity check matrixes.

It should be noted that the above technique may be used to produce multiple expanded parity check matrixes from a base parity check matrix, but embodiments are not limited to this technique. That is, in some embodiments, a group of candidate parity check matrixes may include two or more parity check matrixes that may or may not be related to each other. The parity check matrixes in the group may be formed using any suitable technique, including those previously described or others. For instance, two or more parity check matrixes may be selected or designed independently. As an example, some of the matrixes in the group may be used to generate different codes that may have different codeword lengths and/or code rates in some cases. As another example, some of the matrixes in the group may or may not be of different sizes.

Returning to the method 300, the AP 102 may transmit the LDPC codeword at operation 315 and may transmit the second LDPC codeword at operation 320. It should be noted that the LDPC codewords may be included as part of one or more transmitted signals, and may therefore be processed according to any suitable number of transmit functions. For instance, interleaving, bit-to-symbol mapping and other functions may be used. As another example, mapping of symbols to sub-carriers and/or OFDM symbol periods may be performed as part of generation of OFDM signals.

In some embodiments, the AP 102 may support legacy and non-legacy STAs 103. As an example, one of the LDPC codewords may be encoded for the legacy STA 103 according to the base parity check matrix and may be transmitted for the legacy STA 103. As another example, one of the LDPC codewords may be encoded for the non-legacy STA 103 according to the expanded parity check matrix and may be transmitted for the non-legacy STA 103. As another example, one of the LDPC codewords may be encoded for the non-legacy STA 103 according to the base parity check matrix and may be transmitted for the non-legacy STA 103. These examples are not limiting, however, as the LDPC codewords transmitted by the AP 102 for legacy and/or non-legacy STAs 103 may be encoded using any suitable parity check matrix in some cases.

In some embodiments, the AP 102 may transmit LDPC codewords of different lengths (and therefore encoded according to different parity check matrixes) during overlapping time and/or frequency resources. As an example, a first LDPC codeword for a legacy STA and a second, longer LDPC codeword for a non-legacy STA 103 may be transmitted during a same frame or other time period. Such LDPC codewords may also be transmitted in overlapping frequency resources in some cases.

It should be noted that previous examples may be related to expansion of a single base matrix into one or more expanded parity check matrixes. As an example, the base parity check matrix may include sub-matrixes of size k. The expanded parity check matrixes may include sub-matrixes of size (w*k), where the scaling factor w may be a positive integer such as two, four or other.

However, in some embodiments, multiple base parity check matrixes may be expanded into multiple expanded parity check matrixes. For instance, a standard such as 802.11 or other may support a group of base parity check matrixes that generate LDPC codewords of lengths 648, 1296, and 1944. The different base parity check matrixes may be related to different forward error correction (FEC) coding rates such as 1/2, 2/3, 3/4, 5/6 or other. The group of base parity check matrixes may be expanded into a group of expanded parity check matrixes with the above scaling technique. As an example, for a scaling factor of two, longer LDPC codewords of the same coding rate may be generated, and the lengths may be 2*(648, 1296, 1944) or (1296, 2592, 3888). As another example, for a scaling factor of four, longer LDPC codewords of the same coding rate may be generated, and the lengths may be 4*(648, 1296, 1944) or (2592, 5184, 7776). As another example, the group of base parity check matrixes may be expanded according to multiple scaling factors (such as two and four previously described) to produce multiple groups of expanded parity check matrixes. As another example, when a scaling factor of w is supported, expanded parity check matrixes for any integer between 1 and w may be used. In some cases, some such values may require adjustments to the parity check matrix, size of incoming bits to be encoded or other parameters. For instance, padding of the parity check matrix and/or incoming bit block may be used to realize integer sizes.

At operation 325, one or more Fourier Transform (FT) operations may be performed to produce an OFDM signal that is based at least partly on the first LDPC codeword and/or the second LDPC codeword. In some embodiments, an Inverse Fast Fourier Transform (IFFT) may be performed on sub-carrier values as part of generation of the OFDM signal. As an example, the sub-carrier values may be based on constellation points resulting from bit-to-symbol mappings of the first LDPC codeword and/or second LDPC codeword. For instance, the sub-carrier values used for generation of the OFDM signal during a particular OFDM symbol period may be based at least partly on both LDPC codewords. The LDPC codewords may or may not be of the same length. The sub-carrier values may also be based at least partly on other codewords or bits in some cases. It should be noted that although some of the examples described herein may refer to a first and a second LDPC codeword, embodiments are not so limited, as one LDPC codeword or more than two LDPC codewords may be used in some cases.

The OFDM signal may be transmitted in channel resources comprising multiple sub-carriers at operation 330. In some embodiments, a first LDPC codeword may be transmitted as part of a first OFDM signal that operates according to a first OFDM symbol period and a second LDPC codeword may be transmitted as part of a second OFDM signal that operates according to a second OFDM symbol period. As an example, the first and second OFDM symbol periods may be different. As another example, the first and second OFDM symbol periods may be the same or similar. In some embodiments, an OFDM signal transmitted during a particular symbol period may be based at least partly on both the first and second LDPC codewords, which may or may not be of the same length. Accordingly, an orthogonal frequency division multiple access (OFDMA) technique may be used such that at least a portion of the first and second LDPC codewords are transmitted within at least one of the OFDM symbol periods (or OFDMA symbol period).

It should be noted that OFDM may operate according to an inverse relationship between OFDM symbol period and a sub-carrier spacing measured in frequency. In some embodiments, the first LDPC codeword may be transmitted as part of a first OFDM signal that operates according to a first number of sub-carriers and the second LDPC codeword may be transmitted as part of a second OFDM signal that operates according to a second number of sub-carriers. For instance, in a frequency bandwidth, a sub-carrier spacing may be related to a number of IFFT points used. Accordingly, the first OFDM signal may result from an IFFT operation with a first number of IFFT points and the second OFDM signal may result from an IFFT operation with a second number of IFFT points.

As an example, a first sub-carrier spacing of 312.5 kHz may be used along with a first OFDM symbol period of 3.2 usec. A second sub-carrier spacing of 78.125 kHz may be used along with a second OFDM symbol period of 12.8 usec. The first sub-carrier spacing and OFDM symbol period may be part of operation according to a legacy 802.11 standard while the second sub-carrier spacing and OFDM symbol period may be part of non-legacy operation. As such, a first LDPC codeword length and/or first parity check matrix may be used as part of the legacy operation while a second LDPC codeword length and/or second parity check matrix may be used as part of the HEW operation. The second LDPC codeword may be longer than the first LDPC codeword in some cases. For instance, the non-legacy operation may include high efficiency wireless (HEW) operation according to one or more 802.11 ax standards, although non-legacy operation is not limited as such.

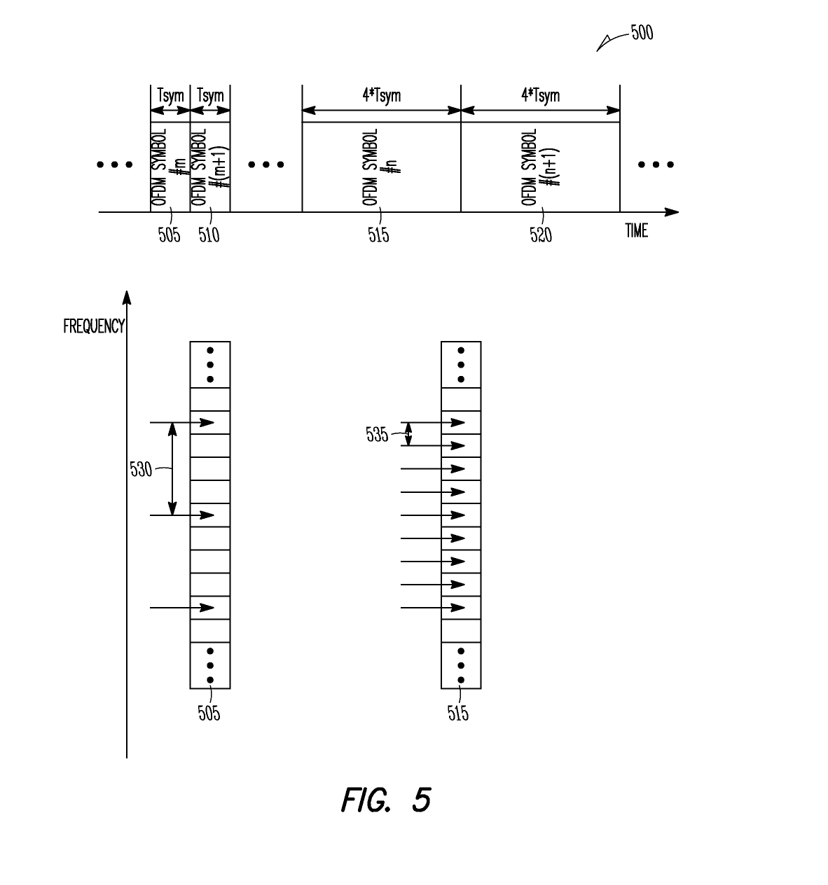

FIG. 5 illustrates an example of arrangement of orthogonal frequency division multiplexing (OFDM) symbol periods and sub-carriers in accordance with some embodiments. It should be noted that the example arrangement 500 shown in FIG. 5 may serve to illustrate some or all of the concepts and techniques described herein, but embodiments are not limited to the example arrangement 500. For instance, embodiments are not limited to the number of OFDM symbol periods, the number of sub-carriers, the lengths of the OFDM symbol periods, and/or the sub-carrier spacings shown.

As shown in the top portion of FIG. 5, in the arrangement 500, one or more OFDM symbol periods 505, 510 that span an OFDM symbol period of Tsym may be transmitted by the AP 102. In addition, one or more OFDM symbol periods 515, 520 that span an OFDM symbol period of 4*Tsym may also be transmitted by the AP 102. As shown in the bottom portion of FIG. 5, a sub-carrier spacing 530 for the OFDM symbol period 505 may be greater than a sub-carrier spacing 535 for the OFDM symbol period 515 by a factor of four. In addition, for a portion of channel resources (such as a 20 MHz portion of frequency described previously), the OFDM symbol period 505 may include a smaller number of sub-carriers in comparison to the OFDM symbol period 515. Accordingly, an IFFT size may be smaller. As an example, a 64-point IFFT may be used to generate the time signal for OFDM symbol period 505 while a 256-point IFFT may be used to generate the time signal for the OFDM symbol period 515.

In some cases, the OFDM symbol periods 505-520 may be included in a same frame. As an example, OFDM symbol periods 505, 510 may be part of a legacy operation while OFDM symbol periods 515, 520 may be part of an HEW operation. As another example, OFDM symbol periods 505, 510 (or others in the same frame that also span an OFDM symbol period of Tsym) may be used for transmission of beacon signals or other control signals in addition to transmission of data for legacy STAs 103. As another example, OFDM symbol periods 515, 520 (or others in the same frame that also span an OFDM symbol period of 4*Tsym) may be used for transmission of data for HEW STAs 103, and may use longer LDPC codewords as part of the data transmission.

Returning to the method 300, at operation 335, the AP 102 may receive an LDPC codeword from the STA 103. In some embodiments, the uplink LDPC codeword may be based on a second parity check matrix different from the parity check matrix used for the LDPC codeword transmitted by the AP 102. In some cases, the AP 102 and the STA 103 may use parity check matrixes of different sizes for LDPC codewords transmitted and/or received. For instance, the STA 103 may be capable of decoding LDPC codes that use a scaling factor of four but may be restricted to legacy encoding or encoding at a scaling factor of one. Other configurations may be used in which the AP 102 and the STA 103 may perform encoding with parity check matrixes that have different scaling factors or the same scaling factors.

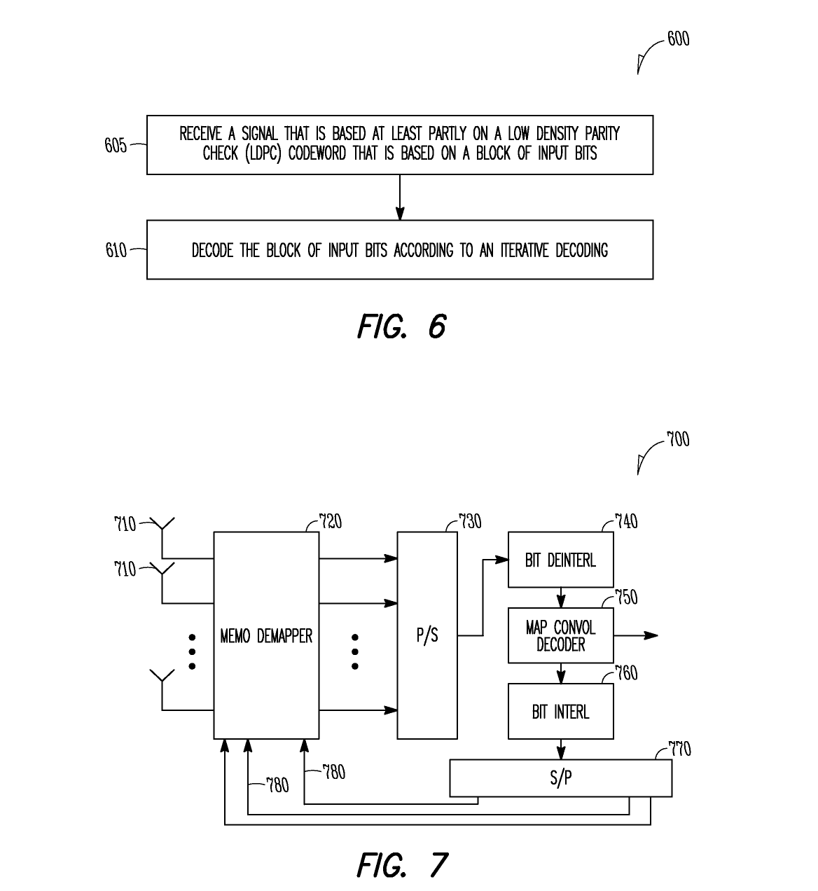

FIG. 6 illustrates the operation of another method of channel sounding in accordance with some embodiments. As mentioned previously regarding the method 300, embodiments of the method 600 may include additional or even fewer operations or processes in comparison to what is illustrated in FIG. 6 and embodiments of the method 600 are not necessarily limited to the chronological order that is shown in FIG. 6. In describing the method 600, reference may be made to FIGS. 1-5 and 7-8, although it is understood that the method 600 may be practiced with any other suitable systems, interfaces and components. In addition, embodiments of the method 600 may refer to APs, STAs, eNBs 104, UEs 102, HEW APs, HEW STAs or other wireless or mobile devices. The method 600 may also refer to an apparatus for an STA 103 and/or AP 102 or other device described above.

It should be noted that the method 600 may be practiced at an STA 103, and may include exchanging of signals or messages with an AP 102. Similarly, the method 300 may be practiced at the AP 102, and may include exchanging of signals or messages with the STA 103. In some cases, operations and techniques described as part of the method 300 may be relevant to the method 600. In addition, embodiments may include operations performed at the STA 103 that are reciprocal or similar to other operations described herein performed at the AP 102. For instance, an operation of the method 600 may include reception of a frame by the STA 103 while an operation of the method 300 may include transmission of the same frame or similar frame by the AP 102.

In addition, previous discussion of various techniques and concepts may be applicable to the method 600 in some cases, including the parity check matrixes, base parity check matrixes, expanded parity check matrixes, sub-matrixes, scaling of sub-matrixes and parity check matrixes, generator matrixes, OFDM signals, legacy and non-legacy STAs 103, legacy and non-legacy operation, and others. Other concepts previously described, such as the channel resources, sub-channels, and sub-carriers may also be applicable to the method 600. In addition, the example representation matrix 400 shown in FIG. 4 and/or the OFDM arrangement 500 shown in FIG. 5 may also be applicable, in some cases.

At operation 605, the STA 103 may receive a signal that is based at least partly on an LDPC codeword. The LDPC codeword may be based on a block of input bits and may be encoded according to a parity check matrix. Previously described techniques may be used, in some cases. For instance, the signal may be based on constellation points generated by operations such as bit-to-symbol mapping and/or interleaving performed on the LDPC codeword. The signal may be an OFDM signal, although not limited as such.

In some embodiments, the parity check matrix for the LDPC codeword may be related to HEW operation for the STA 103, although the scope of embodiments is not limited in this respect. In some cases, the signal received at the STA 103 may also be based on one or more other LDPC codewords, which may or may not necessarily be intended for the STA 103. For instance, a second parity check matrix related to legacy operation may be used to generate the other LDPC codewords, which may be shorter than the LDPC codeword that is intended for the STA 103.

Although not limited as such, the parity check matrixes used for the LDPC codewords may be included in a group of candidate parity check matrixes as described earlier. That is, a base matrix may be expanded to produce an expanded parity check matrix, and LDPC codewords for the expanded parity check matrix may be longer than LDPC codewords for the base matrix. The base matrix and the expanded parity check matrix may include zero matrixes and shifted identity matrixes in some cases.

At operation 610, the block of input bits may be decoded by the STA 103 according to an iterative decoding technique. It should be noted that embodiments are not limited to the use of iterative decoding techniques, as non-iterative decoding techniques may also be used in some cases. In any case, an output may include a block of decoded bits.

FIG. 7 illustrates an example of an iterative decoder in accordance with some embodiments. The iterative decoder 700 may receive one or more signals at receive antennas 710. As an example, MIMO techniques may be used. As another example, the signals received on different antennas may be related to independent data streams that may be transmitted by the AP 102 on different transmit antennas. As another example, the signals received on different antennas may at least partly depend on some of the same data bits as part of diversity operation. The MIMO demapper 720 may rearrange or reconfigure the incoming received signals from the receive antennas 710 accordingly. For instance, soft metrics may be produced by the MIMO demapper 720, including log-likelihood ratios (LLRs) or others.

The soft metrics may be concatenated and/or rearranged by the parallel-to-serial block 730, and may be passed for processing by the deinterleaver 740, decoder 750, and interleaver 760. The decoder 750 may produce soft metrics in addition to decoded bits. As part of an iterative decoding, the soft metrics from the decoder 750 may be passed back through the serial-to-parallel block 770 for conversion back into a suitable format for input at 780 back to the MIMO demapper 720.

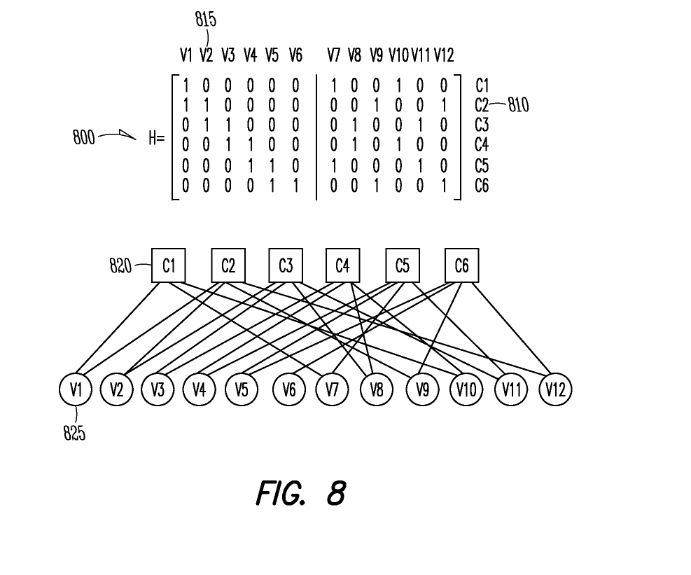

FIG. 8 illustrates an example of a parity check matrix that may be used for iterative decoding in accordance with some embodiments. The parity check matrix 800 may include one or more check nodes 820 that may be related to the rows 810. The parity check matrix 800 may also include one or more variable nodes 825 that may be related to the columns 815. Accordingly, a relationship between the check nodes 820 and the variable nodes 825 may be based on the parity check matrix 800 and may be visualized as shown in FIG. 8.

In some embodiments, a first set of soft metrics may be determined for the variable nodes 825. A second set of soft metrics may be determined for the check nodes 820, and may be based at least partly on the first set of soft metrics and/or the received signal. A third set of soft metrics may be determined for the variable nodes 825, and may be based at least partly on the second set of soft metrics and/or the received signal. A fourth set of soft metrics may be determined for the check nodes 820, and may be based at least partly on the third set of soft metrics and/or the received signal. Such iterations may be continued as desired. The additional iterations may produce additional gains in terms of decoded error rate, in some cases.

As previously described, LDPC codewords may be generated according to different parity check matrixes of different sizes. As an example, a first parity check matrix may be associated with legacy operation or control blocks while a second, larger parity check matrix may be associated with non-legacy operation. Accordingly, LDPC codewords generated according to the second parity check matrix may be longer than LDPC codewords generated according to the first parity check matrix. The non-legacy operation may include HEW operation according to a standard such as 802.11ax, in which a sub-carrier spacing may be reduced in comparison to legacy operation while an OFDM symbol period may be increased in comparison to legacy operation. Accordingly, the LDPC decoder 700 may be configured to decode LDPC codes of varying sizes. As an example, the STA 103 may be configured for non-legacy operation, and may be configured to decode LDPC codewords generated according to both legacy and non-legacy parity check matrixes.

In some cases, parallelism may be realized for decoding of LDPC codes. For instance, each variable node may be related to a different portion of the check nodes and therefore a soft metric for each variable node may be related to a portion of the check nodes. In addition, each check node may be related to a different portion of the variable nodes and therefore a soft metric for each check node may be related to a portion of the variable nodes. Multiple soft metrics may be computed in parallel, in some cases, and such parallel computations may be performed using multiple processing units (PUs). In some embodiments, each PU may include a dedicated portion of available computational resources, such as a subset of gates on a field programmable gate array (FPGA). In some embodiments, each PU may include or may be part of a separate processor. These examples are not limiting, however, as any suitable technique or arrangement in which computational resources are configured to determine the soft metrics in a parallel or non-parallel manner may be used.

In some embodiments, the STA 103, or an apparatus for the STA 103, may include the PUs and the PUs may be configured to perform decoding operations and techniques described herein. It should also be noted that the AP 102 or another device, or an apparatus for the AP 102 or other device, may also include PUs configured to perform decoding operations and techniques described herein.

As an example, computation of the soft metrics for the variable nodes may be performed by multiple PUs, and subsequent computation of the soft metrics for the check nodes may also be performed by multiple PUs. For instance, for a parity check matrix that includes 1000 variable nodes and 500 check nodes, 10 PUs may be used such that each PU performs soft metric computations for 100 of the variable nodes. In a subsequent operation, each PU may perform soft metric computations for 50 of the check nodes.

As previously described, decoding of longer LDPC codewords may require more computation than for shorter LDPC codewords. For instance, the parity check matrix may be larger for the longer LDPC codewords, and therefore may include more variable nodes and/or check nodes. To accommodate such an increase, additional PUs may be used. In some embodiments, a group of legacy PUs may be configured to decode legacy LDPC codewords generated according to a legacy parity check matrix. Non-legacy LDPC codewords generated according to a larger non-legacy parity check matrix may be decoded using the group of legacy PUs and a group of additional PUs. That is, the additional PUs may be used (with or without one or more of the legacy PUs) to accommodate the longer LDPC codewords. As such, a decoding latency may be reduced in comparison to a decoding latency when the non-legacy codewords are decoded using the legacy PUs.

In some embodiments, the legacy LDPC codewords may be decoded using the legacy PUs while the non-legacy LDPC codewords may be decoded using the additional PUs in addition to, or instead of, the legacy PUs. These embodiments are not limiting, however, as a combination of the legacy PUs and the additional PUs may also be used to decode the legacy LDPC codewords in some embodiments. In some embodiments, quasi-cyclic LDPC codes (QC-LDPCC) may be used. For instance, the parity check matrixes may include sub-matrixes that include matrixes of zeros and shifted identity matrixes.

An example apparatus for an access point (AP) is disclosed herein. The apparatus may comprise hardware processing circuitry and transceiver circuitry. The hardware processing circuitry may be configured to encode a block of input bits according to a parity check matrix to produce a low density parity check (LDPC) codeword. The hardware processing circuitry may configure the transceiver circuitry to transmit the LDPC codeword. The parity check matrix may be included in a group of candidate parity check matrixes that includes a base parity check matrix and an expanded parity check matrix. The base parity check matrix may include a group of base sub-matrixes arranged within the base parity check matrix according to a grid pattern. The expanded parity check matrix may include expansions of the group of base sub-matrixes arranged within the expanded parity check matrix according to the grid pattern.

In some examples, an LDPC codeword length may be smaller for the base parity check matrix than for the expanded parity check matrix. In some examples, the group of base sub-matrixes may include one or more zero matrixes of a base size and one or more identity matrixes of the base size shifted by a set of shift values. The expansions of the group of base sub-matrixes may include zero matrixes of an expanded size that is larger than the base size, and may further include identity matrixes of the expanded size shifted by the set of shift values.

In some examples, for grid indexes at which the base parity check matrix includes zero matrixes, the expanded parity check matrix may include zero matrixes. For grid indexes at which the base parity check matrix includes shifted identity matrixes, the expanded parity check matrix may include shifted identity matrixes. In some examples, the group of candidate parity check matrixes may further include a second expanded parity check matrix. The second expanded parity check matrix may include zero matrixes of a second expanded size and identity matrixes of the second expanded size shifted by the set of shift values. In some examples, when the LDPC codeword is transmitted for a legacy user station (STA), the base parity check matrix may be used for the encoding. In some examples, when the LDPC codeword is transmitted for a non-legacy STA, the expanded parity check matrix may be used for the encoding.

In some examples, the encoding according to the parity check matrix may include application of a generator matrix to the block of input bits. The generator matrix may be based on a null space of the parity check matrix. In some examples, the LDPC codeword may be encoded according to the base parity check matrix. The hardware processing circuitry may be further configured to encode a second block of input bits according to the expanded parity check matrix to produce a second LDPC codeword. The hardware processing circuitry may further configure the transceiver circuitry to transmit the second LDPC codeword.

In some examples, the LDPC codeword may be transmitted for a legacy user station (STA) and the second LDPC codeword may be transmitted for a non-legacy STA. The second LDPC codeword may be longer than the first LDPC codeword. In some examples, the LDPC codeword may be transmitted as part of a first orthogonal frequency division multiplexing (OFDM) signal that operates according to a first OFDM symbol period. The second LDPC codeword may be transmitted as part of a second OFDM signal that operates according to a second OFDM symbol period that is longer than the first OFDM symbol period. In some examples, the LDPC codeword may be transmitted as part of a first orthogonal frequency division multiplexing (OFDM) signal that operates according to a first OFDM sub-carrier spacing. The second LDPC codeword may be transmitted as part of a second OFDM signal that operates according to a second OFDM sub-carrier spacing that is smaller than the first OFDM sub-carrier spacing.

In some examples, the LDPC codeword and the second LDPC codeword may be transmitted as part of an orthogonal frequency division multiple access (OFDMA) signal that comprises multiple sub-carriers and spans multiple OFDMA symbol periods. During a first OFDMA symbol period, a first portion of the sub-carriers may be based at least partly on the LDPC codeword and a second portion of the sub-carriers may be based at least partly on the second LDPC codeword. The OFDMA signal may be transmitted during a transmission opportunity (TXOP) for a contention based access. The TXOP may include a time period allocated for transmission by the AP.

In some examples, the LDPC codeword may be transmitted for a user station (STA). The hardware processing circuitry may further configure the transceiver circuitry to receive, from the STA, a second LDPC codeword based on a second parity check matrix different from the parity check matrix used for the transmitted LDPC codeword. In some examples, the apparatus may be configured to operate according to one or more wireless local area network (WLAN) protocols. In some examples, the apparatus may further comprise one or more antennas coupled to the transceiver circuitry for the transmission of the LDPC codeword.

An example of a non-transitory computer-readable storage medium that stores instructions for execution by one or more processors of an access point (AP) to perform operations for communication is also disclosed herein. The operations may configure the one or more processors to encode a first block of input bits according to a first parity check matrix to produce a first low density parity check (LDPC) codeword of a first length. The operations may further configure the one or more processors to encode a second block of input bits according to a second parity check matrix to produce a second LDPC codeword of a second length. The operations may further configure the one or more processors to transmit the first codeword for a legacy user station (STA) and the second codeword for a non-legacy STA. The first codeword may be smaller than the second codeword. The first parity check matrix may include multiple sub-matrixes and the second parity check matrix may be formed by an expansion of the sub-matrixes.

In some examples, the operations may further configure the one or more processors to transmit, during an orthogonal frequency division multiplexing (OFDM) frame, an OFDM signal that is based at least partly on the first and second codewords. In some examples, the sub-matrixes of the first parity check matrix may include matrixes of zeros and identity matrixes shifted according to a set of shift values. The expansion of the sub-matrixes may include an expansion of the matrixes of zeros by a codeword length scaling and further includes an expansion of the identity matrixes and a shifting of the expanded identity matrixes by the shift values. In some examples, the operations may further configure the one or more processors to receive, from the non-legacy STA, an uplink LDPC codeword that is encoded according to the first parity check matrix.

An example of a method of communication performed at an access point (AP) is also disclosed herein. The method may comprise encoding a block of input bits according to a parity check matrix to produce a low density parity check (LDPC) codeword and transmitting the LDPC codeword. The parity check matrix may be selected from a group of candidate parity check matrixes that includes a base parity check matrix and an expanded parity check matrix. The base parity check matrix may include a group of base sub-matrixes arranged within the base parity check matrix according to a grid pattern. The expanded parity check matrix may include expansions of the group of base sub-matrixes arranged within the expanded parity check matrix according to the grid pattern.

In some examples, the group of base sub-matrixes may include one or more zero matrixes of a base size and one or more identity matrixes of the base size shifted by a set of shift values. The expansions of the group of base sub-matrixes may include zero matrixes of an expanded size that is larger than the base size, and may further include identity matrixes of the expanded size shifted by the set of shift values.

An example of an apparatus for a user station (STA) is also disclosed herein. The apparatus may comprise hardware processing circuitry and transceiver circuitry. The hardware processing circuitry may configure the transceiver circuitry to receive a signal that is based at least partly on a low density parity check (LDPC) codeword, the LDPC codeword based on a block of input bits encoded according to a parity check matrix. The hardware processing circuitry may be configured to decode the block of input bits according to an iterative decoding based on the parity check matrix. The parity check matrix may be included in a group of candidate parity check matrixes that includes a base parity check matrix and an expanded parity check matrix. The base parity check matrix may include a group of base sub-matrixes arranged within the base parity check matrix according to a grid pattern. The expanded parity check matrix may include expansions of the group of base sub-matrixes arranged within the expanded parity check matrix according to the grid pattern.

In some examples, the group of base sub-matrixes may include one or more zero matrixes of a base size and one or more identity matrixes of the base size shifted by a set of shift values. The expansions of the group of base sub-matrixes may include zero matrixes of an expanded size that is larger than the base size, and may further include identity matrixes of the expanded size shifted by the set of shift values. In some examples, the parity check matrix may include a group of variable nodes and a group of check nodes. The iterative decoding may include a determination of a first set of soft metrics for the variable nodes based at least partly on the received signal. The iterative decoding may further include a determination of a second set of soft metrics for the check nodes based at least partly on the first set of soft metrics. The iterative decoding may include a determination of a third set of soft metrics for the variable nodes based at least partly on the second set of soft metrics.

In some examples, the apparatus may further comprise one or more antennas coupled to the transceiver circuitry for the reception of the signal. In some examples, the apparatus may comprise multiple antennas and the reception of the signal may include a multiple-input multiple-output (MIMO) reception of the signal.

The Abstract is provided to comply with 37 C.F.R. Section 1.72(b) requiring an abstract that will allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. An apparatus for an access point (AP), the apparatus comprising hardware processing circuitry and transceiver circuitry, the hardware processing circuitry configured to:
encode a block of input bits according to a parity check matrix to produce a low density parity check (LDPC) codeword; and
configure the transceiver circuitry to transmit the LDPC codeword,
wherein the parity check matrix is included in a group of candidate parity check matrixes that includes a base parity check matrix and an expanded parity check matrix,
wherein the base parity check matrix includes a group of base sub-matrixes arranged within the base parity check matrix according to a grid pattern, and
wherein the expanded parity check matrix includes expansions of the group of base sub-matrixes arranged within the expanded parity check matrix according to the grid pattern.

2. The apparatus according to claim 1, wherein an LDPC codeword length is smaller for the base parity check matrix than for the expanded parity check matrix.

3. The apparatus according to claim 1, wherein:
the group of base sub-matrixes includes one or more zero matrixes of a base size and one or more identity matrixes of the base size shifted by a set of shift values, and
the expansions of the group of base sub-matrixes include zero matrixes of an expanded size that is larger than the base size, and further includes identity matrixes of the expanded size shifted by the set of shift values.

4. The apparatus according to claim 3, wherein:
for grid indexes at which the base parity check matrix includes zero matrixes, the expanded parity check matrix includes zero matrixes, and
for grid indexes at which the base parity check matrix includes shifted identity matrixes, the expanded parity check matrix includes shifted identity matrixes.

5. The apparatus according to claim 3, wherein:
the group of candidate parity check matrixes further includes a second expanded parity check matrix, and
the second expanded parity check matrix includes zero matrixes of a second expanded size and identity matrixes of the second expanded size shifted by the set of shift values.

6. The apparatus according to claim 1, wherein when the LDPC codeword is transmitted for a legacy user station (STA), the base parity check matrix is used for the encoding.

7. The apparatus according to claim 6, wherein when the LDPC codeword is transmitted for a non-legacy STA, the expanded parity check matrix is used for the encoding.

8. The apparatus according to claim 1, wherein the encoding according to the parity check matrix includes application of a generator matrix to the block of input bits, the generator matrix based on a null space of the parity check matrix.

9. The apparatus according to claim 1, wherein:
the LDPC codeword is encoded according to the base parity check matrix,
the hardware processing circuitry is further configured to encode a second block of input bits according to the expanded parity check matrix to produce a second LDPC codeword,
the hardware processing circuitry is to further configure the transceiver circuitry to transmit the second LDPC codeword.

10. The apparatus according to claim 9, wherein:
the LDPC codeword is transmitted for a legacy user station (STA) and the second LDPC codeword is transmitted for a non-legacy STA, and
the second LDPC codeword is longer than the first LDPC codeword.

11. The apparatus according to claim 10, wherein:
the LDPC codeword is transmitted as part of a first orthogonal frequency division multiplexing (OFDM) signal that operates according to a first OFDM symbol period, and
the second LDPC codeword is transmitted as part of a second OFDM signal that operates according to a second OFDM symbol period that is longer than the first OFDM symbol period.

12. The apparatus according to claim 10, wherein:
the LDPC codeword is transmitted as part of a first orthogonal frequency division multiplexing (OFDM) signal that operates according to a first OFDM sub-carrier spacing, and
the second LDPC codeword is transmitted as part of a second OFDM signal that operates according to a second OFDM sub-carrier spacing that is smaller than the first OFDM sub-carrier spacing.

13. The apparatus according to claim 10, wherein:
the LDPC codeword and the second LDPC codeword are transmitted as part of an orthogonal frequency division multiple access (OFDMA) signal that comprises multiple sub-carriers and spans multiple OFDMA symbol periods,
during a first OFDMA symbol period, a first portion of the sub-carriers are based at least partly on the LDPC codeword and a second portion of the sub-carriers are based at least partly on the second LDPC codeword, and
the OFDMA signal is transmitted during a transmission opportunity (TXOP) for a contention based access, the TXOP including a time period allocated for transmission by the AP.

14. The apparatus according to claim 1, wherein:
the LDPC codeword is transmitted for a user station (STA),
the hardware processing circuitry is to further configure the transceiver circuitry to receive, from the STA, a second LDPC codeword based on a second parity check matrix different from the parity check matrix used for the transmitted LDPC codeword.

15. The apparatus according to claim 1, wherein the apparatus is configured to operate according to one or more wireless local area network (WLAN) protocols.

16. The apparatus according to claim 1, the apparatus further comprising one or more antennas coupled to the transceiver circuitry for the transmission of the LDPC codeword.

17. A non-transitory computer-readable storage medium that stores instructions for execution by one or more processors of an access point (AP) to perform operations for communication, the operations to configure the one or more processors to:
encode a first block of input bits according to a first parity check matrix to produce a first low density parity check (LDPC) codeword of a first length,
encode a second block of input bits according to a second parity check matrix to produce a second LDPC codeword of a second length,
transmit the first codeword for a legacy user station (STA) and the second codeword for a non-legacy STA,
wherein the first codeword is smaller than the second codeword, and
wherein the first parity check matrix includes multiple sub-matrixes and the second parity check matrix is formed by an expansion of the sub-matrixes.

18. The non-transitory computer-readable storage medium according to claim 17, the operations to further configure the one or more processors to transmit, during an orthogonal frequency division multiplexing (OFDM) frame, an OFDM signal that is based at least partly on the first and second codewords.

19. The non-transitory computer-readable storage medium according to claim 17, wherein:
the sub-matrixes of the first parity check matrix include matrixes of zeros and identity matrixes shifted according to a set of shift values,
the expansion of the sub-matrixes includes an expansion of the matrixes of zeros by a codeword length scaling and further includes an expansion of the identity matrixes and a shifting of the expanded identity matrixes by the shift values.

20. The non-transitory computer-readable storage medium according to claim 15, the operations to further configure the one or more processors to receive, from the non-legacy STA, an uplink LDPC codeword that is encoded according to the first parity check matrix.

21. A method of communication performed at an access point (AP), the method comprising:
encoding a block of input bits according to a parity check matrix to produce a low density parity check (LDPC) codeword; and
transmitting the LDPC codeword,
wherein the parity check matrix is selected from a group of candidate parity check matrixes that includes a base parity check matrix and an expanded parity check matrix,
wherein the base parity check matrix includes a group of base sub-matrixes arranged within the base parity check matrix according to a grid pattern, and
wherein the expanded parity check matrix includes expansions of the group of base sub-matrixes arranged within the expanded parity check matrix according to the grid pattern.

22. The method according to claim 21, wherein:
the group of base sub-matrixes includes one or more zero matrixes of a base size and one or more identity matrixes of the base size shifted by a set of shift values, and
the expansions of the group of base sub-matrixes include zero matrixes of an expanded size that is larger than the base size, and further includes identity matrixes of the expanded size shifted by the set of shift values.

23. An apparatus for a user station (STA), the apparatus comprising hardware processing circuitry and transceiver circuitry, the hardware processing circuitry configured to:
configure the transceiver circuitry to receive a signal that is based at least partly on a low density parity check (LDPC) codeword, the LDPC codeword based on a block of input bits encoded according to a parity check matrix, and
decode the block of input bits according to an iterative decoding based on the parity check matrix,
wherein the parity check matrix is included in a group of candidate parity check matrixes that includes a base parity check matrix and an expanded parity check matrix,
wherein the base parity check matrix includes a group of base sub-matrixes arranged within the base parity check matrix according to a grid pattern, and
wherein the expanded parity check matrix includes expansions of the group of base sub-matrixes arranged within the expanded parity check matrix according to the grid pattern.

24. The apparatus according to claim 23, wherein:
the group of base sub-matrixes includes one or more zero matrixes of a base size and one or more identity matrixes of the base size shifted by a set of shift values, and
the expansions of the group of base sub-matrixes include zero matrixes of an expanded size that is larger than the base size, and further includes identity matrixes of the expanded size shifted by the set of shift values.

25. The apparatus according to claim 23, wherein:
the parity check matrix includes a group of variable nodes and a group of check nodes, and
the iterative decoding includes:
a determination of a first set of soft metrics for the variable nodes based at least partly on the received signal,
a determination of a second set of soft metrics for the check nodes based at least partly on the first set of soft metrics, and
a determination of a third set of soft metrics for the variable nodes based at least partly on the second set of soft metrics.

26. The apparatus according to claim 23, the apparatus further comprising one or more antennas coupled to the transceiver circuitry for the reception of the signal.

27. The apparatus according to claim 26, wherein the apparatus comprises multiple antennas and the reception of the signal includes a multiple-input multiple-output (MIMO) reception of the signal.
